(19) United States
(12) Patent Application Publication
(10) Pub. No.: US 2016/0322253 A1
(43) Pub. Date: Nov. 3, 2016

(54) Substrate Carrier For Solar Cells

(71) Applicant: Chung King Enterprise Co., Ltd., Taoyuan City (TW)

(72) Inventor: Hui-Chan Yen, Taoyuan City (TW)

(21) Appl. No.: 14/847,447

(22) Filed: Sep. 8, 2015

(30) Foreign Application Priority Data
Apr. 30, 2015 (TW) 104206680

(51) Int. Cl. H01L 21/687; H01L 21/67

(52) U.S. Cl. CPC H01L 21/68785; H01L 21/68757; H01L 21/67075; H01L 21/68735; H01L 21/68778; H01L 21/68771

(57) ABSTRACT

A substrate carrier for solar cells, utilized in a wet etching process, comprising: two side plates; at least a side rod, connected respectively to an outer portion on each side of the two side plates; at least a bottom rod, connected respectively to a lower portion on each side of the two side plates; at least a press rod, connected respectively to an upper portion on each side of the two side plates. Wherein, a space formed by formed by the two side plates, the side rod, the bottom rod, and press rod, is used to receive at least a solar cell substrate. Wherein, a plurality of first teeth are arranged axially along axes of the side rod and the press rod, such that each of the first teeth maintains a point-to-point contact with each of the solar cell substrates.

### BACKGROUND OF THE INVENTION

1. Field of the Invention

The present invention relates to a substrate carrier, and in particular to a substrate carrier for carrying and supporting solar cell substrates to perform wet etching in a manufacturing process, so as to form pyramid structure of superior quality on the surface of solar cell substrate, hereby raising the photo-electric conversion efficiency of the solar cells.

2. The Prior Arts

In the process of manufacturing solar cells, dry etching or wet etching is first performed, to form a pyramid structure on the surface of solar cell substrate, and that is used to produce a photo-electric conversion layer.

In general, in the process of manufacturing solar cells, a carrier is used to carry and support solar cell substrates. Then, a robotic arm is provided to hold the carrier, to go through a variety of processes relating to acid and alkali etching, rinsing, and drying steps for the solar cell substrates contained therein. In this process, the acid and alkali etching fluids may include the various strong acid and strong alkali etching such as potassium hydroxide, sodium hydroxide, sulphuric acid, nitric acid, hydrofluoric acid, and aqueous ammonia. The rinsing fluid may include highly purified fluid, and de-ionized water, to wash and clean the residue etching fluid remaining on the substrate. Finally, a drying step is performed to dry the substrate.

However, the material and the structure of the conventional carrier is not capable of withstanding strong acid and strong alkali etching fluids, and the high temperature incurred during such etching processes. In other words, the conventional carrier is not capable of withstanding strong acid and strong alkali, and it can only endure process temperature of about 60° C.˜80° C. As such, it can only withstand acid/alkali etching fluid of low concentration (<20%), such that its lifetime is reduced, and it has to be replaced after 100˜500 times of usage. In addition, hydrophobicity of the conventional carrier is rather insufficient, the residual etching fluid tends to remain around the solar cell substrate even after it has been rinsed, so after acid/alkali etching, the pin mark or invalid area around the solar cell substrate tends to be significantly large, so as to cause decrease of yield for the solar cells. For example, due to insufficient hydrophobicity of the conventional carrier, the residues of strong alkali etching fluid in the previous step may still remain on the substrate, even after through the rinsing process. As such, in case the substrates having strong alkali etching fluid residue thereon are transferred into the subsequent strong acid etching step, that could lead to acid-base neutralization, so as to adversely affect the result of substrate etching, and that could even endanger the life of the operator.

Therefore, the design and performance of a conventional substrate carrier is not quite satisfactory, and it leaves much room for improvement.

### SUMMARY OF THE INVENTION

In view of the aforementioned problems and drawbacks of the prior art, the present invention provides a substrate carrier for solar cells, in order to overcome the shortcomings of the prior art.

A main objective of the present invention is to provide a substrate carrier for solar cells that is made of a specific material having superior hydrophobicity capability, so as to achieve the characteristics of high temperature resistance, erosion resistance, high cleanness, low pollution (or low particle release), high hydrophobicity, and high abrasion resistance, thus increasing the lifetime of the carrier itself significantly. In this way, in particular, when the carrier is used to perform wet etching, due to the superior hydrophobicity of the carrier, not only can the residue etching fluids be reduced by 20%˜80% in volume, but a superb pyramid structure can also be formed (an acute angle greater than 20° can be formed between the reflection surface of the pyramid structure and the surface of the substrate) on the surface of solar cell substrate, so as to raise the photo-electric conversion efficiency of the solar cells according to the invention.

In the prior art, for the solar cell made through using the conventional carrier, the pyramid structure formed on the substrate may have an acute angle of less than 20°, so that the photo-electric conversion efficiency of solar cell thus made is less than 16%. However, in the present invention, for the solar cell made by using this type of new carrier, the acute angle of the pyramid structure can be formed greater than 20°, so as to raise its photo-electric conversion efficiency of the solar cell to about 17%˜25%.

In pursuit of the objective mentioned above, the present invention provides a substrate carrier made of PFA for solar cells, comprising: two side plates; at least a side rod, connected respectively to an outer portion at each side of the two side plates; at least a bottom rod, connected respectively to a lower portion at each side of the two side plates; and at least a press rod, connected respectively to an upper portion at each side of the two side plates. There is a space formed by the two side plates, the at least a side rod, the at least a bottom rod, and the at least a press rod, such that the space may receive at least a solar cell substrate. There are a plurality of teeth arranged axially and equally spacing along axes of the side rod and the press rod, such that each of the teeth maintains a point-to-point contact with each solar cell substrate. A recess is provided on each side of the side plate to fasten a droplet projection for the press rod in a rotation way while an inclined opening is extended below the recess.

In the present invention, the carrier made of PFA (Tetrafluoroethylene-perfluoroalkyl Vinyl Ether Copolymer) is suitable for a wet chemical etching process, and the carrier is provided with the characteristics of high temperature resistance, erosion resistance, high cleanliness, low pollution, and abrasion resistance, and thus raising its lifetime significantly. Meanwhile, through the provision of the inclined openings, the carrier is designed to have good hydrophobicity, thereby effectively preventing residue of etching fluid from remaining around the solar cell substrate, and thus restricting the pin mark or ineffective area around the substrate to less than 1 mm². In addition, a superb pyramid structure is formed on the surface of solar cell substrate, with the angle between the reflection surface and the bottom surface of the pyramid structure greater than 20°, and thus raising the photo-electric conversion efficiency of solar cells thus made significantly.

Further scope of the applicability of the present invention will become apparent from the detailed descriptions given hereinafter. However, it should be understood that the detailed descriptions and specific examples, while indicating preferred embodiments of the present invention, are given by way of illustration only, since various changes and modifications within the spirit and scope of the present invention will become apparent to those skilled in the art from this detailed descriptions.

### BRIEF DESCRIPTION OF THE DRAWINGS

The related drawings in connection with the detailed descriptions of the present invention to be made later are described briefly as follows, in which:

FIG. 1 is a perspective view of a substrate carrier for solar cells according to the present invention;

FIGS. 2A, 2B, and 2C are a side view, a top view, and a front view respectively of a first teeth according to a first embodiment of the present invention;

FIGS. 3A, 3B, 3C, and 3D are a perspective view, a front view, a top view, and a side view respectively of the first teeth and a second teeth according to the first embodiment of the present invention;

FIGS. 4A and 4B are a side view and a front view respectively of the first teeth according to a second embodiment of the present invention;

FIGS. 5A, 5B, and 5C are a side view, a top view, and a front view respectively of the first teeth according to a third embodiment of the present invention;

FIGS. 6A and 6B are a side view and a front view respectively of the first teeth according to a fourth embodiment of the present invention;

FIG. 7 is an enlarged view of a press rod according to the present invention;

FIGS. 8A and 8B are schematic diagrams of a droplet projection and a U-shape notch respectively according to the present invention;

FIG. 9 is a schematic diagram of an L-shape notch according to the present invention; and

FIGS. 10A and 10B are schematic diagrams respectively of the side plate and a hook slot hung on the side plate according to the present invention.

### DETAILED DESCRIPTION OF THE PREFERRED EMBODIMENT

The purpose, construction, features, functions and advantages of the present invention can be appreciated and understood more thoroughly through the following detailed description with reference to the attached drawings.

The present invention relates to a substrate carrier for solar cells. In the present invention, the term “radial” refers to a direction extending along the radius of a rod; while the term “axial” refers to a direction extending along an axis or lengthwise direction while passing through the center of the rod. As such, the “radial” (direction) and the “axial” (direction) are perpendicular to each other.

In general, the substrate carrier for solar cells is used in wet chemical etching process, to carry and support the substrate for the solar cells. In this way, the solar cell substrate 5 can be immersed into the high temperature and strong etching fluid (including but not limited to potassium hydroxide, sodium hydroxide, sulphuric acid, nitric acid, hydrofluoric acid, and aqueous ammonia), highly purified water or pure water, so as to perform repeated wet chemical etching and rinsing.

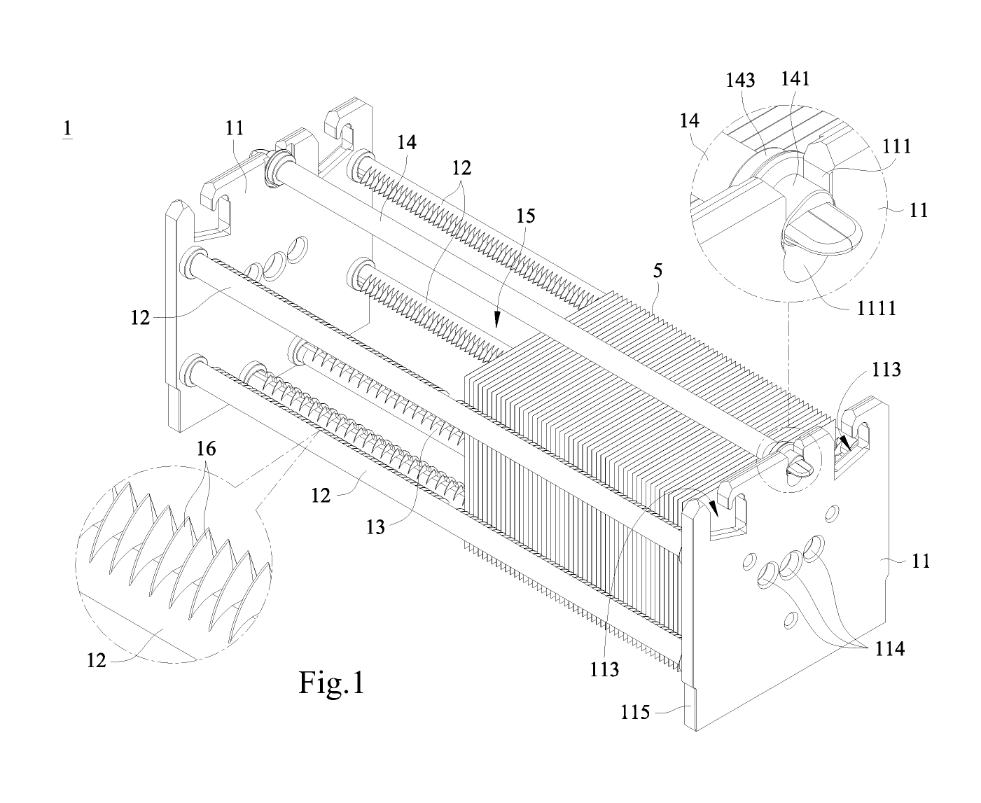

Refer to FIG. 1 for a perspective view of a substrate carrier for solar cells according to the present invention. As shown in FIG. 1, the substrate carrier for solar cells includes: two side plates 11, at least a side rod 12, at least a bottom rod 13, and at least a press rod 14. The side rod, the bottom rod, and the press rod are of a cylinder shape.

Wherein, the two side plates 11 are located at the two ends of the carrier 1.

Two sides of the side rods 12 are each connected to the outer portion of each of the two side plates 11.

Two sides of the bottom rods 13 are each connected to the lower portion of each of the two side plates 11. A space 15 is formed by the two side plates 11, the side rods 12, and the bottom rods 13, so as to receive at least a solar cell substrate 5 in a carrier 1 for a wet chemical etching process.

Two sides of the press rod 14 are each connected to the upper portion of each of the two side plates 11.

In addition, a plurality of first teeth 16 are arranged axially and with equally spacing along the axis of the side rods 12 and the press rods 14, such that the solar cell substrates 5 can be put into the carrier 1, and be arranged between two adjacent first teeth 16. As such, as viewed in the top view cross section, each of the first teeth 16 and each of the solar cell substrates 5 are maintained in a point-to-point contact. In this way, during performing the wet chemical etching for the solar cell substrates 5, the shielded area during etching and rinsing is greatly reduced, so that the etching and rinsing process can be performed more thoroughly and completely, so as to provide good signal transmission, and improve the yield.

The upper portions of the two side plates 11 are each provided with a recess 111, to guidingly engage the droplet projections 141 of the press rods 14, and an inclined opening 1111 is extended outwardly from the recess 111 so as to provide high hydrophobicity through the inclined opening 111, thereby draining out effectively the residual etching fluid or rinsing fluid between the substrate and the carrier.

Summing up the above, through the PFA material of the carrier 1, in the wet chemical etching process, the carrier 1 could have the characteristics of high temperature endurance, erosion resistance, high cleanliness, low pollution or low particle release, and abrasion resistance, so as to increase the lifetime of the carrier 1 significantly. Moreover, with the provision of the inclined opening 1111, the carrier 1 is able to have high hydrophobicity, so as to prevent the residual chemical etching fluid from remaining around the solar cell substrate 5, thus reducing pin mark or invalid regions around the substrate 5. Besides, it could cause the photo-electric conversion layer of the solar cell substrate to form a well-defined pyramid structure, such that the acute angle formed on the reflection surface of the pyramid structure along the horizontal surface of the substrate is greater than 20°, hereby raising the anti reflection efficiency of the photo-electric conversion layer, and its photo-electric conversion efficiency to exceed over 17%.

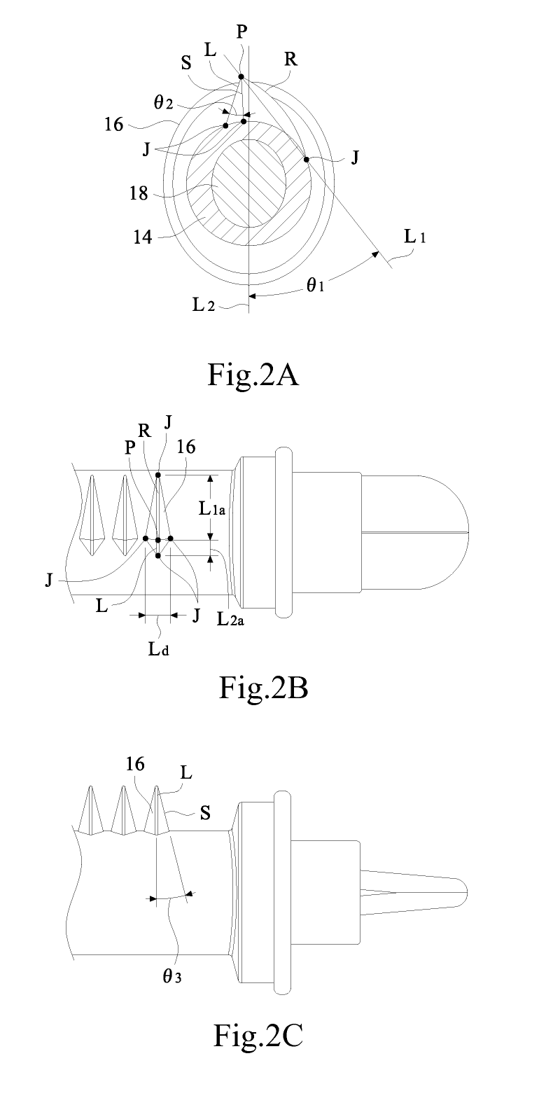

Refer to FIGS. 2A-2B for a side and a top views of first teeth according to a first embodiment of the present invention. As shown in FIG. 2A, each of the first teeth 16, based on its side (axial) view, is formed by a longer arc edge R, a shorter line edge L, a pair of symmetric slant sides S, and an apex P. The apex P is defined as the highest point of the first teeth 16 (namely, located at the upper or far most part of the rod). As shown in FIG. 2B, each of the first teeth 16, based on its top (lengthwise) view, is connected to the side rod 12 and the press rod 14 respectively at the four junctions J, such that each of the first teeth 16 is able to support the respective solar cell substrate 5 through the pair of slant sides S (both Js located at the right and left positions of P) in a point-to-point contact manner.

Moreover, in the first embodiment, in the side view of the first teeth 16 is shown as an asymmetry fin. The radius of curvature of the arc edge R is between 3 mm and 500 mm. An angle θ1, formed between the first line L1 passing through the apex P and the junction J, and the second line L2 passing through the apex P and the center of the rod O, is between 10° and 85°; while an angle θ2, formed between the line edge L and the second line L2, is 18°˜45°. Through the design of the size and angle of the structure mentioned above, the carrier is able to have optimal hydrophobicity, so that the solar cells thus produced could achieve the highest photo-electric conversion efficiency.

Then, refer back to FIGS. 2A and 2B. As viewed from the top, the first teeth 16 is shown to have a first radial length L1a, a second radial length L2a, and an axial length Ld. The first radial length L1a is defined as the length from the apex P to the junction J along the direction of arc edge R. The second radial length L2a is defined as the length from the apex P to the junction J along the direction of line edge L. The second radial length L2a is about 0.1 to 0.9 times the first radial length L1a; while the axial length Ld is the longest axial length of the first teeth 16, and is about 0.2 to 0.8 times the length of the first radial length L1a. Through the design of the size and angle of the structure mentioned above, the carrier is able to have optimal hydrophobicity, so that the solar cells thus produced could achieve the highest photo-electric conversion efficiency.

Subsequently, refer to FIG. 2C for a front view of the first teeth according to the first embodiment of the present invention. As shown in FIG. 2C, the first teeth 16 is provided with a pair of slant sides S and a line edge L, such that an angle θ3 is formed by the slant sides S and the line edge L, and the angle θ3 has a range of 1°˜45° (preferably 8°˜20°). Through the design of the size and angle of the structure mentioned above, the carrier is able to have optimal hydrophobicity, so that the solar cells thus produced could achieve the highest photo-electric conversion efficiency.

Refer again to FIG. 1, in which it is shown that for the carrier 1, the plurality of first teeth 16 are arranged axially and with equally spacing along the axis of the bottom rod 13.

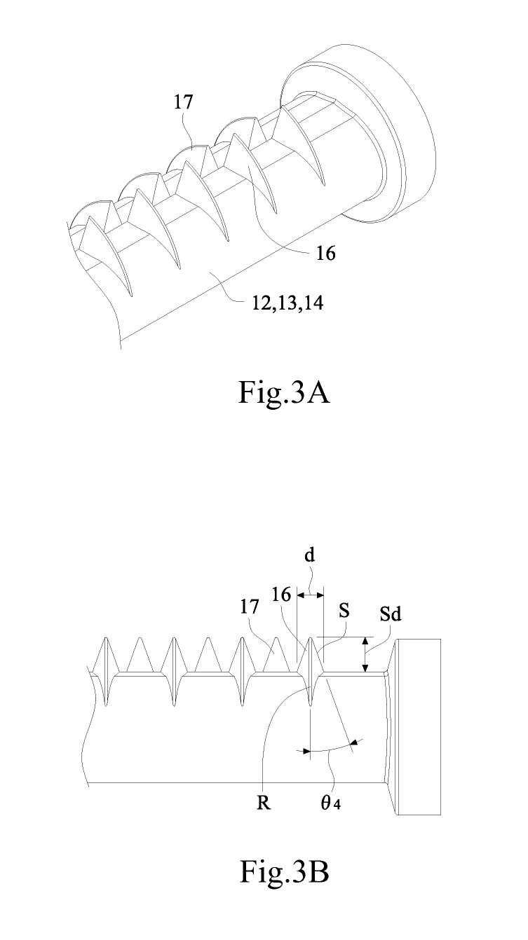

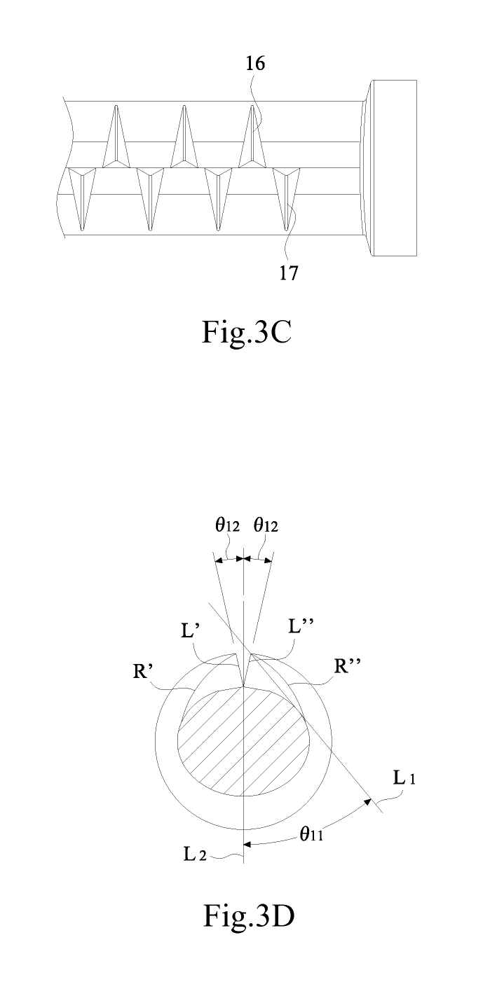

Now, refer to FIG. 3A for a perspective view of second teeth according to the first embodiment of the present invention. As shown in FIG. 3A, a plurality of second teeth 17 are further arranged axially and with equally spacing along one of the axis of the side rod 12, the bottom rod 13, and the press rod 14.

In the present embodiment, the plurality of first teeth 16 and the plurality of second teeth 17 are arranged axially in a staggered arrangement. The first teeth 16 and the second teeth 17 are designed to have similar shape and structure, so that the solar cell substrates 5 can be placed into the space 15 of the carrier 1 to prevent adhesion of substrates to teeth within the carrier. When the wet chemical etching is performed, the shape and structure of the first teeth 16 and the second teeth 17 can be adjusted based on the fluid flow direction, speed in the various acid-alkali tanks, or acid alkali fluid, temperature, concentration in the various acid-alkali tanks.

Refer to FIG. 3D for a side view of the first teeth and the second teeth according to the first embodiment of the present invention. As shown in FIG. 3D, as viewed from the side view, the first teeth 16 and the second teeth 17 jointly form a symmetry fin; while the symmetry fin is formed by a longer arc edge R′ of the first teeth 16 and a longer arc edge R″ of the second teeth 17. The radius of curvature of each arc edge is 3 mm˜500 mm. An angle θ11 is formed between a line L1 passing through the apex and the junction of the teeth, and a line L2 passing through the apex and the center of the rod, and thus having a range of 10°˜60° (preferably 8°˜20°). Also, an angle θ12 is formed between Line 2, and a line passing through the shorter line edge L′ or L″ of either the first teeth 16 or the second teeth 17, and thus having a range of ˜18°˜15.° Through the design of the size and angle of the structure mentioned above, the carrier is able to have optimal hydrophobicity, so that the solar cells thus produced could achieve the highest photo-electric conversion efficiency.

Refer to FIG. 3C for a top view of the first teeth and the second teeth according to the first embodiment of the present invention. As shown in FIG. 3C, the first teeth 16 and the second teeth 17 are formed to present the adjacent teeth in an up-and-down configuration.

Refer to FIG. 3B for a front view of the first teeth and the second teeth according to the first embodiment of the present invention. As shown in FIG. 3B, as viewed from the front, for the first teeth 16 or the second teeth 17, the radial distance Sd of the slant sides S is about 0.8 to 5 times the axial length d; while an angle θ4 formed by the slant sides S and the arc edge R is between 1° and 45°. Through the design of the size and angle of the structure mentioned above, the carrier is able to have optimal hydrophobicity, so that the solar cells thus produced could achieve the highest photo-electric conversion efficiency.

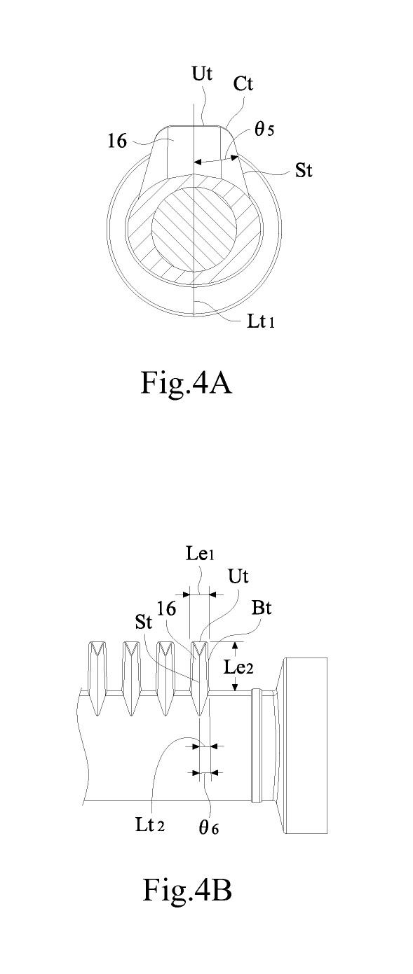

In a second embodiment of the present invention, as shown in FIG. 4A, as viewed from the side, the first teeth 16 is in a form of an isosceles trapezoid, and is formed by a top face Ut, a pair of chamfer faces Ct, a pair of slant faces St, and a bottom portion. The chamfer face Ct has a radius of curvature between 1 mm and 30 mm. An angle θ5 is formed between a slant face St and a line Lt1 passing the center of the top face Ut and the center of the rod, and the angle θ5 has a range of 1°˜60°. Through the design of the size and angle of the structure mentioned above, the carrier is able to have optimal hydrophobicity, so that the solar cells thus produced could achieve the highest photo-electric conversion efficiency.

In the present embodiment, as shown in FIG. 4B, the first teeth 16 is shown in its front view as provided with the top face Ut, the chamfer face Ct, the slant face St, and the two slant side faces Bt. An angle θ6 is formed between the slant side face Bt and a line Lt2 passing the center of the top face Ut and the center of the rod, and the angle θ6 has a range of 1°˜45°. The top face Ut has a maximum axial length Le1, while the slant side face Bt has a maximum radial length Le2. The maximum radial length Le2 is about 0.5 to 10 times the maximum axial length Le1. Through the design of the size and angle of the structure mentioned above, the carrier is able to have optimal hydrophobicity, so that the solar cells thus produced could achieve the highest photo-electric conversion efficiency.

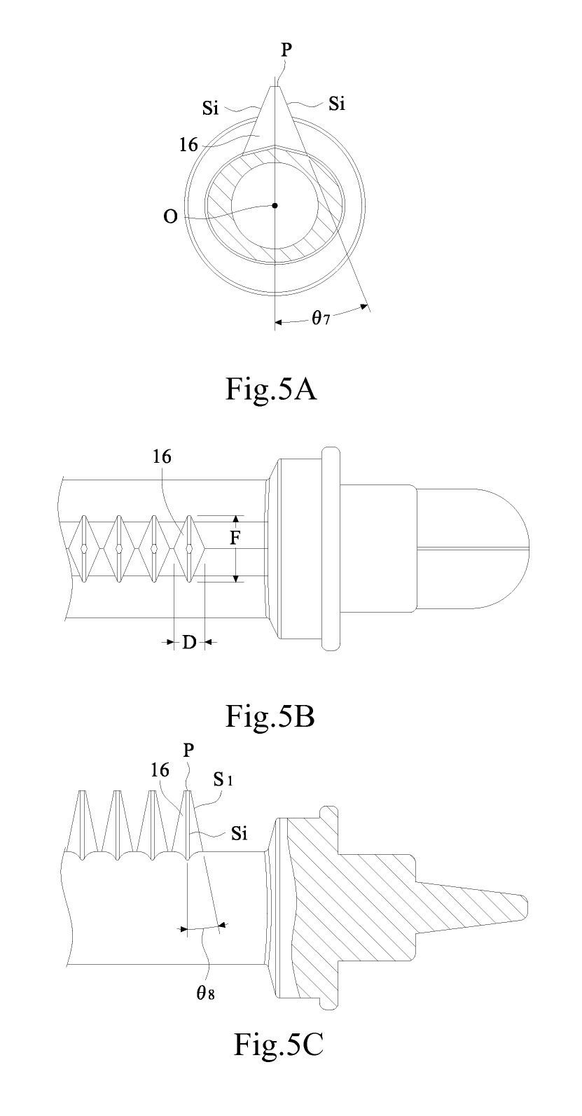

Then, refer to FIG. 5A for a side view of a first teeth according to a third embodiment of the present invention. As shown in FIG. 5A, the first teeth 16 are shown in its side view as an isosceles triangle having an apex P. The isosceles triangle is provided with two identical slant sides Si. An angle θ7 is formed by one of the slant sides, and a line L extending from the apex P to the center O of the rod (namely, the side rod 12, the bottom rod 13, or the press rod 14), and the angle θ7 has a range of 3°˜60°. Through the design of the size and angle of the structure mentioned above, the carrier is able to have optimal hydrophobicity, so that the solar cells thus produced could achieve the highest photo-electric conversion efficiency.

Refer to FIG. 5B for a top view of the first teeth according to the third embodiment of the present invention. As shown in FIG. 5B, the first teeth 16 are shown in its top view as a rhomb. The rhomb is shown with a maximum angle radial side F (radial side F facing the maximum angle), and a minimum angle axial side D (axial side D facing the minimum angle), for the minimum angle axial side D being 0.2 to 5 times the maximum angle radial side F. Through the design of the size and angle of the structure mentioned above, the carrier is able to have optimal hydrophobicity, so that the solar cells thus produced could achieve the highest photo-electric conversion efficiency.

Refer to FIG. 5C for a front view of the first teeth according to the third embodiment of the present invention. As shown in FIG. 5C, the first teeth 16 is shown in its front view as having the apex P, the isosceles slant side Si, and two-side slant side S1, and an angle θ8 is formed by the isosceles slant side Si and the two-side slant side S1, and the angle θ8 has a range of 1°˜45°. Through the design of the size and angle of the structure mentioned above, the carrier is able to have optimal hydrophobicity, so that the solar cells thus produced could achieve the highest photo-electric conversion efficiency.

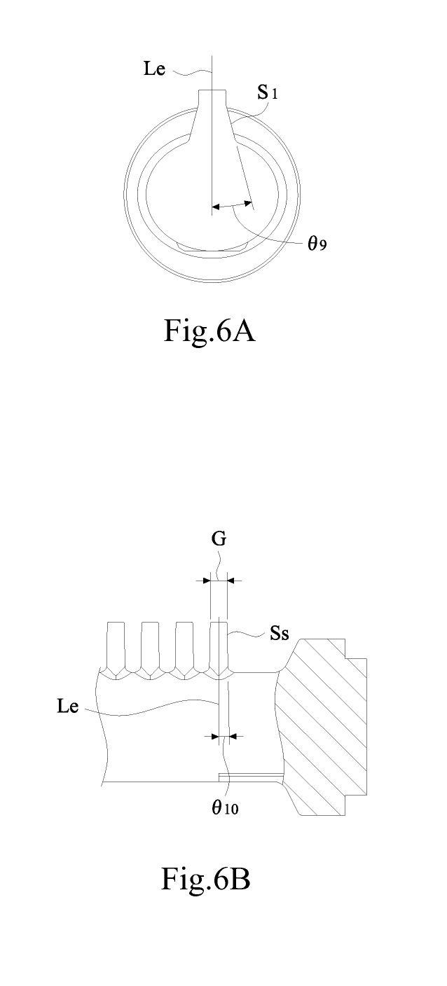

In a fourth embodiment of the present invention, as shown in FIG. 6A, the first teeth 16 is shown in its side view as a gradually varying ellipsoid, provided with a minimum ellipse of a major axis (first) at its top end, and a maximum ellipse of the other major axis (second) at its bottom end; a major axial slant side S1 between the two major axes; and an angle θ9 is formed between the major axial slant side S1, and a line Le passing through the center of the ellipsoid and the center of the rod, and the angle θ9 has a range of 1°˜45°. Through the design of the size and angle of the structure mentioned above, the carrier is able to have optimal hydrophobicity, so that the solar cells thus produced could achieve the highest photo-electric conversion efficiency.

Then, refer to FIG. 6B for a front view of the first teeth according to the fourth embodiment of the present invention. As shown in FIG. 6B, the first teeth 16 is shown in its front view as having a minimum ellipse of the minor axis (first), and a maximum ellipse of the other minor axis (second), and a minor axial slant side Ss between the two minor axes. An angle θ10 is formed between the minor axial slant side Ss, and a line Le passing through the center of the ellipsoid and the center of the rod, and the angle θ10 has a range of 1°˜45°. The minor axial slant side Ss is about 0.5 to 5 times the minimum ellipse minor axial length G. Through the design of the size and angle of the structure mentioned above, the carrier is able to have optimal hydrophobicity, so that the solar cells thus produced could achieve the highest photo-electric conversion efficiency.

Refer again to FIG. 1, as shown in FIG. 1, the carrier 1 made of PFA material is provided with the following characteristics: a density of between 2 and 2.5, a melting point between 280° C.˜350° C., a tensile strength of between 20˜38 MPa, an elastic modulus of between 445˜730 MPa at room temperature, and a limiting oxygen index (LOI) greater than 95%. In the case, the carrier 1 is used in wet chemical etching process, and has the following advantages: high temperature resistance, erosion resistance, high cleanliness, low pollution (or low particle release), and abrasion resistance, thus raising its lifetime significantly.

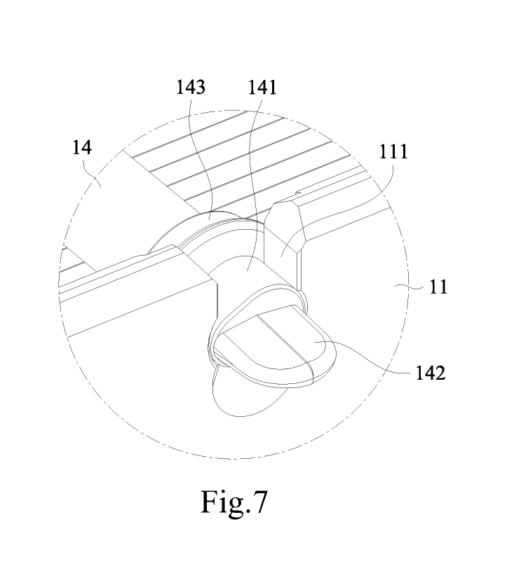

Refer to FIG. 7 for an enlarged view of the press rod according to the present invention. As shown in FIG. 7, the droplet projection 141 is extended outwardly from the press rod 14 to form a protrusion 142 of flat shape, for the sake of a user to hold it to position the press rod 14 into the recess 111 of the side plate 11.

As the droplet projection 141 of the press rod 14 is extended inwardly to form a round protrusion 143, such that when the press rod 14 is positioned and guided in the recess 111 of the side plate 11, the round protrusion 143 is pressed or abutted tightly against the inner portion of the side plate 11, so as to prevent the press rod 14 from the left or right shifting due to being pressed by the substrate, thus adversely affecting the positioning of press rod 14 in the side plate 11.

When the press rod 14 is guidingly positioned in the recess 111 of the side plate 11, the first teeth 16 disposed on the press rod 14 are faced toward and pressed against the upper portion of the solar cell substrate 5.

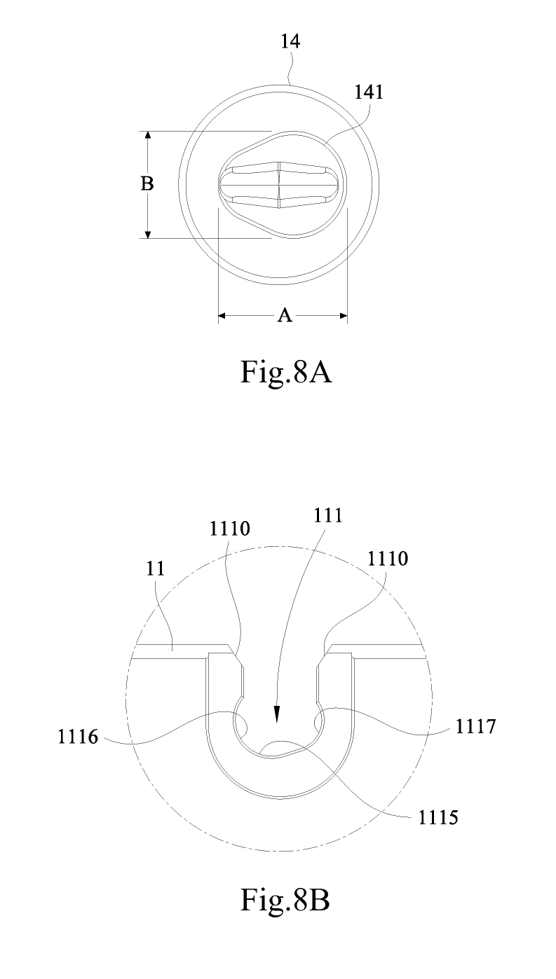

Then, refer to FIGS. 8A and 8B respectively for schematic diagrams of the droplet projection and U-shape notch according to the present invention. As shown in FIGS. 8A and 8B, the droplet projection 141 of the press rod 14 is provided with a major axis and a minor axis, such that the length A of the major axis is about 1.1 to 1.5 times of the length B of the minor axis. The recess 111 of the side plate 11 is further provided with a U-shape notch 1115 corresponding to the major axis and the minor axis. A pair of slant faces 1110 are respectively disposed on both left and right entry sides of the recess 111 to guide the droplet projection 141 of the press rod 14 for engagement with the U-shape notch 1115. The arc shape of the U-shape notch 1115 is designed to match the shape of the major axis, so that the major axis is slidable within the U-shape notch 1115. The minor axis is not allowed to be slidable within the U-shape notch 1115, so as to ensure that the press rod 14 is rotatable in a specific direction for a specific distance, hereby making the press rod 14 position rotatably in the recess 111 of the side plate 11.

As mentioned above, the recess 111 of the side plate 11 is further provided with the U-shape notch 1115 corresponding to the major axis and the minor axis. A slant face 1110 is respectively disposed on both left and right entry sides of the U-shape notch 1115 for engagement with the press rod 14. Wherein, on each of both sides of the bottom end of the U-shape notch 1115, it is provided respectively with a first diameter arc portion 1116 and a second diameter arc portion 1117 to restrict the movement of the major axis and the minor axis of the droplet projection 141. As such, when the first diameter arc portion 1116 and the second diameter arc portion 1117 are different, the press rod 14 is allowed to rotate only in a specific direction (clockwise or counter clockwise) for a specific distance. When the first diameter arc portion 1116 and the second diameter arc portion 1117 are the same, the press rod 14 is allowed to have a clockwise or counter clockwise rotation for a specific distance. Therefore, regardless if the diameters of the first diameter arc portion 1116 and the second diameter arc portion 1117 are equal, the press rod can be rotatably positioned in the recess of the side plate.

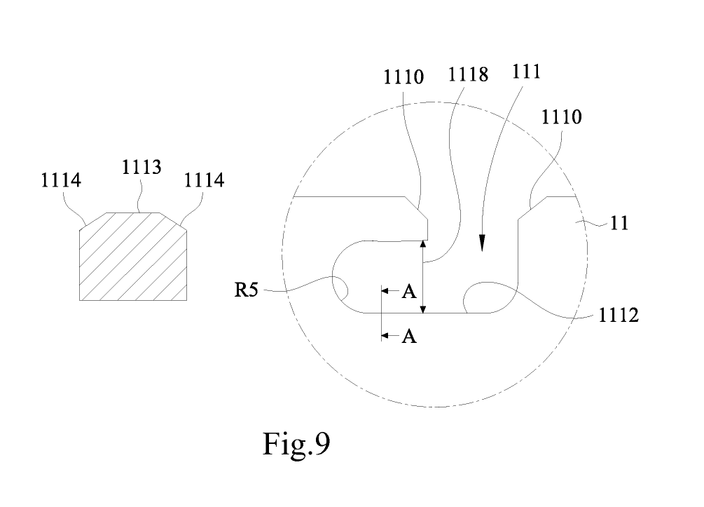

Refer to FIG. 9 for a schematic view of an L-shape notch according to the present invention. As shown in FIG. 9, the recess 111 of the side plate 11 is further provided with an L-shape notch 1112. A pair of slant faces 1110 are respectively disposed on both left and right entry sides of the L-shape notch 1112 to guide the droplet projection 141 of the press rod 14 for engagement with the recess 111. On the left side of the L-shape notch 1112, it is extended with an inner opening 1118, and a side round arc R5 is extended from the inner opening 1118, to match and in cooperation with the top end of the droplet projection 141. Wherein, the diameter of the side round arc R5 is slightly greater than the length of the inner opening 1118, so as to ensure that the press rod 14 is allowed only to displace in a specific direction (toward the left-side) for a specific distance, such that the press rod 14 is fastened and engaged in the recess 1111 of the side plate 11. Wherein, a guiding slant face 1114 is respectively provided on two sides of the lower portion 1113 of the L-shape notch 1112, such that the L-shape notch 1112 is able to have higher hydrophobicity, so as to drain out effectively and thoroughly the residual chemical etching fluid.

The positions of connecting the side plates 11 with the side rods 12 and with the bottom rods 13 are provided with a connecting and melting place (not shown), and in each of the connecting and melting places is provided with a connecting and melting portion (not shown). Through the connecting and melting portions, the ends of the side rods 12 and bottom rods 13 are connected and melted to the connecting and melting portions of the side plates 11.

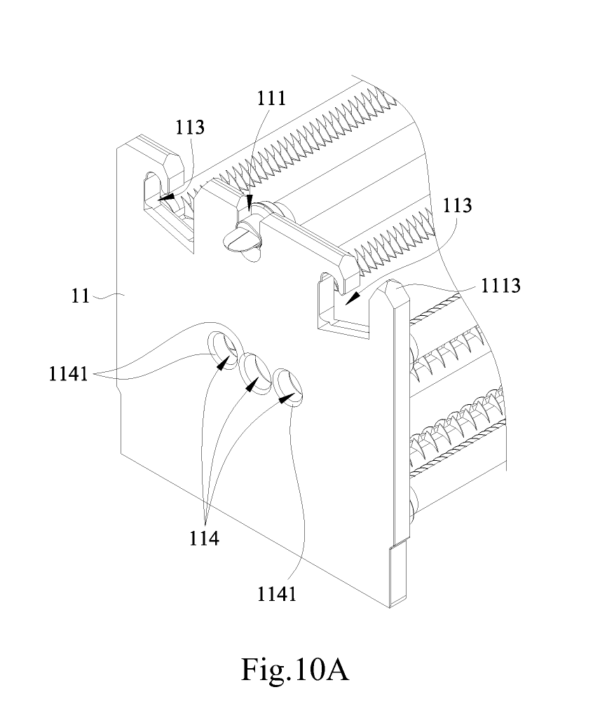

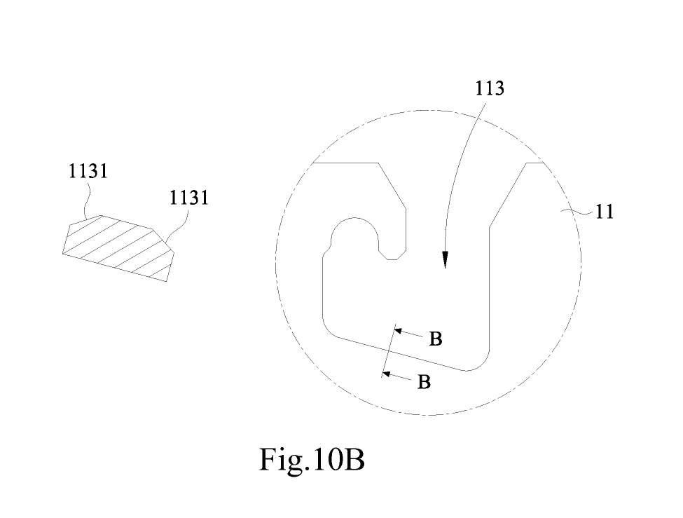

Refer to FIG. 10A for a schematic view of a side plate according to the present invention. As shown in FIG. 10A, a hook slot 113 is provided near each of both sides of the recess 111 of the side plate 1. The hook slot 113 is used by a robotic arm (not shown) to hold the carrier 1. In the central portion of the side plate 11 is provided with a plurality of positioning holes 114, for the user to grasp the carrier 1, or position and engage the carrier 1 into a processing machine.

Refer to FIG. 10B for a schematic diagram of the hook slot according to the present invention. As shown in FIG. 10B, a guide slant face 1131 is disposed respectively in the hook slot 113, and particularly at the corner of the side plate 11 close to the hook slot 113, and inside the positioning hole 114. The guide slant face 1131 is formed at an angle θ, having a range of 10°˜80°, thus providing high hydrophobicity. In addition, the recess 111 is provided with an inclined opening 1111, such that when the carrier 1 is going through a wet etching process, the residual etching fluid can be drained out speedily (namely, the residual etching fluid can be remained by 20%˜80% reduction in volume); and when the carrier 1 is going through a drying process, the drying time can be reduced by 12.5%.

Compared with the prior art, in accordance with the present invention, the parameters for experiment are measured as follows: the carrier 1 is used to carry 156 mm×156 mm solar cell substrates (silicon-based wafer substrate), to put into an etching machine, at experiment temperature of 85° C.˜95° C., with the etching fluid of hydrogen fluoride (HF), hydrochloric acid (HCL), and Potassium hydroxide (KOH).

Refer again to FIG. 1, along a side of the side plate 11 is further provided with a retraction section 115, so as to facilitate the carrier 1 to be positioned to engage a protrusion section (not shown), when the carrier 1 is put into a wet etching tank (not shown) in a wet etching process.

Above the retraction section 115 of the side plate 11 is further disposed a RFID tag (not shown), in which the related data of solar cell substrate 5 is recorded (for example, type of substrate, customer name, manufacturing method . . . etc), so as to facilitate the manufacturing follow-up process of the carrier 1.

In the present invention, the manufacturing method for making solar cell substrate includes the following steps:

Firstly, providing a carrier 1, so as to receive and carry a plurality of solar cell substrates 5.

Next, transporting the carrier 1 to go through a wet etching process, so as to perform etching of the solar cell substrates 5;

Then, transporting the carrier 1 to go through a rinsing process, so as to rinse the etching fluid on the carrier 1 and the solar cell substrates 5, to obtain the finished product of the solar cell substrates 5; and

Finally, transporting the carrier 1 to go through a drying process, so as to dry the solar cell substrates 5.

Wherein, the design and structure of the carrier 1 are described in the embodiments mentioned above.

The wet etching process is performed in an operation temperature 85° C.˜95° C. The etching fluid is selected from one in a group consisting of: hydrogen fluoride (HF), hydrochloric acid (HCL), and Potassium hydroxide (KOH). The dimension of the solar cell substrate is 156 mm×156 mm in length and width respectively.

Refer again to FIG. 2A, as shown in FIG. 2A, the rod of the carrier 1 made of PFA material, can be further provided with a reinforcement portion 18 doped with carbon fiber, so as to raise effectively the pressure endurance of the rod to support the solar cell substrate. Herein, the rod mentioned above refers to the side rod 12, bottom rod 13, and press rod 14.

Through the material and features of the carrier 1 (as shown in Table 1), the carrier 1 used in the wet chemical etching process is provided to have the characteristics of high temperature resistance, erosion resistance, high cleanliness, low pollution (or low particle release), and abrasion resistance (as shown in Table 2), thus increasing its lifetime significantly.

TABLE 1
material and features of the carrier 1 making use of PFA

| | American Standard Test Method | |
|---|---|---|
| characteristics | (ASTM) | characteristic value |
| density | No. D792 | 2~2.5 g/cc |
| melting point | No. D4591 | 280° C.~350° C. |
| tensile strength | No. D638 | 20~38 MPa (at 23° C.) |
| elastic modulus | No. D790 | 445~730 MPa |
| | | (at 23° C.) |
| limiting oxygen | No. D2863 | >95% |
| index (LOI) | | |

TABLE 2
carrier features (present invention vs Prior Art)

| test item | present invention | prior art |
|---|---|---|
| temperature | 120° C.~160° C. | 60° C.~80° C. |
| resistance | | |
| acid alkali resistance | acid-alkali etching | acid-alkali etching fluid |
| | fluid concentration | concentration <20% |
| | >20% | |
| hydrophobicity | highest by 20%~80% | poor |
| photo-electric | 16%~25% | 10%~16% |
| conversion efficiency | | |
| acute angle formed in | >20° | <20° |
| pyramid reflection | | |
| surface | | |
| number of usage | more than 1000 times | 100~500 times |

When the solar cell substrates are placed in the carrier of the present invention to perform wet etching, through the superior hydrophobicity of the carrier, the residual etching fluid can be greatly reduced in volume by 20%˜80%. Further, a superior pyramid structure can be well-formed on the surface of the solar cell substrate, such that the acute angle formed between the reflection surface of the pyramid and the surface of the substrate can be greater than 20°, so as to raise the photo-electric conversion efficiency of the solar cell to 17%˜25%.

The size of the solar cell substrate (such as silicon wafer) can be set at the dimension: 156 mm×156 mm. The temperature of the etching tank is set at 85° C.˜95° C., while the etching fluids in the etching tank include etching fluids of HF, HCL, KOH. Through the improved hydrophobicity of the carrier, the solar cell substrates can thus be obtained, and the invalid region (pin mark) on each solar substrate can be reduced to less than 1 mm² as verified by the aforementioned tests and experiments.

In addition, the guide slant face is provided respectively at the corner of the side plate and in the positioning hole in which a guiding angle is provided in a range of 10°˜80°, thus leading to excellent hydrophobicity. As such, it is able to avoid the residual etching fluid and rinsing fluid remaining around the solar cell substrate, hereby reducing the invalid region (pin mark) around the solar cell substrate to less than 1 mm².

In contrast, for the conventional carrier, the acid-alkali etching fluid tends to remain around the carrier, so as to cause the invalid region (pin mark) for the solar cell to be around 1˜10 mm². As such, not only the yield of the solar cells thus produced is decreased, but its photo-electric conversion efficiency is also reduced to less than 16%.

Moreover, in the present invention, the carrier is made to have a structure of better hydrophobicity, together with proper adjustment of the material features (as shown in Table 1), residual etching fluid and rinsing fluid remaining on the substrate can be reduced in volume by 20%˜80%. Also, in the drying process of the solar cell substrates, the drying speed can be raised by more than 12.5%. In other words, compared with the Prior Art, the drying time can thus be reduced by 12.5%.

In the present invention, the carrier is made into a structure of better hydrophobicity, that includes but is not limited to the following structure characteristics: the point-to-point contact structure for the teeth and solar cell substrates; the angle formed in the teeth, its radial/axial size and structure; side plate and the guide slant face of the positioning hole, to achieve any of the functions and effects or their combinations as shown in Table 2. In addition, though as shown in FIG. 1, for a carrier 1, a plurality of the first teeth 16 is arranged axially and with equal spacing along the axis of the side rods 12, the bottom rods 13, and the press rods 14; it should be noted that the present invention could include the embodiment that, no first teeth 16 are arranged along the axis of the bottom rods 13.

The above detailed description of the preferred embodiment is intended to describe more clearly the characteristics and spirit of the present invention. However, the preferred embodiments disclosed above are not intended to be any restrictions to the scope of the present invention. Conversely, its purpose is to include the various changes and equivalent arrangements which are within the scope of the appended claims.

What is claimed is:

1. A substrate carrier for solar cells, in a wet etching process, comprising:
two side plates;
at least a side rod, connected respectively to an outer portion on each side of the two side plates;
at least a bottom rod, connected respectively to a lower portion on each side of the two side plates;
at least a press rod, connected respectively to an upper portion on each side of the two side plates;
wherein a space is formed by the two side plates, the at least a side rod, the at least a bottom rod, and the at least a press rod so as to receive at least a solar cell substrate;
wherein a plurality of first teeth are arranged axially and equally spacing along axes of the side rod and the press rod, such that each of the first teeth maintains a point-to-point contact with each of the solar cell substrates;
wherein a recess is provided on each side of the side plate so as to guidingly engage a droplet projection of the press rod, and the recess is further extended to form an opening with an outwardly inclined surface; and
wherein the carrier is made of PFA (Tetrafluoroethylene-perfluoroalkyl Vinyl Ether Copolymer).

2. The substrate carrier for solar cells as claimed in claim 1, wherein each of the first teeth is formed by an arc edge, a line edge, a pair of symmetric slant sides, and an apex, the apex defining a highest point of the first teeth, the arc edge being longer than the line edge, each of the first teeth connecting the side rod and the press rod respectively at four junctions, such that each of the first teeth supports the respective solar cell substrates through the pair of slant sides in the point-to-point contact.

3. The substrate carrier for solar cells as claimed in claim 2, wherein each of the first teeth is, in a side view, configured to present an asymmetry fin, the arc edge having a radius of curvature of between 3 mm and 500 mm; wherein an angle formed between a first line passing through the apex and the junction, and a second line passing through the apex and a center of the rod, has its range of 10°˜85° while an angle is formed between the line edge and the second line having its range of −18°˜45°; wherein each of the first teeth is, in a top view, configured to present a first radial length, a second radial length, and an axial length, the first radial length defining the length from the apex to the junction along the direction of arc edge, while the second radial length defining the length from the apex to the junction along the direction of line edge; wherein the second radial length is 0.1 to 0.9 times the first radial length, the axial length is the longest axial length of the first teeth, and is 0.2 to 0.8 times the length of the first radial length; wherein each of the first teeth is, in a front view, configured to present the pair of slant sides and the line edge, and an angle formed between the slant sides and the line edge has a range of 1°˜45°.

4. The substrate carrier for solar cells as claimed in claim 3, wherein the plurality of first teeth are further arranged axially and equally spacing along the axis of the bottom rod.

5. The substrate carrier for solar cells as claimed in claim 4, further comprising a plurality of second teeth arranged axially and equally spacing along the axis of one of the side rods, the bottom rods, and the press rods; wherein the first teeth and the second teeth are arranged axially in a staggered arrangement, the first teeth and the second teeth being designed to have the same shape and structure;
wherein the first teeth and the second teeth are, in a side view, jointly configured to present a symmetry fin;
wherein the first teeth and second teeth are, in a top view, configured to present the adjacent teeth arranged in an up-and-down configuration;
wherein the first teeth and the second teeth are, in a front view, configured to present that a radial distance of the slant side is 0.8 to 5 times the axial length; and
wherein an angle formed by the slant side and the arc edge is between 1° and 45°.

6. The substrate carrier for solar cells as claimed in claim 1, wherein each of the first teeth is, in a side view, configured to present a form of an isosceles trapezoid which is formed by a top face, a pair of chamfer faces, a pair of inclined faces, and a bottom portion, the each chamfer face having a radius of curvature between 1 mm and 30 mm, an angle being formed between the each inclined face and a line passing a center of the top face and the center of the rod, and having a range of 1°˜60°; wherein each of the first teeth is, in a front view, configured to present the top face, the chamfer face, the inclined face, and two slant side faces, an angle being formed between the each slant side face and a line passing the center of the top face and the center of the rod, and having a range of 1°˜45°; wherein the top face has a maximum axial length while the each slant side face has a maximum radial length, the maximum radial length being 0.5 to 10 times the maximum axial length.

7. The substrate carrier for solar cells as claimed in claim 1, wherein each of the first teeth is, in a side view, configured to present an isosceles triangle having an apex, the isosceles triangle provided with two identical isosceles slant sides, an angle formed by one of the slant sides, and a line extending from the apex to the center of the rod, having a range of 3°˜60°; wherein, each of the first teeth is, in a top view, configured to present a rhombus, the rhombus having a maximum diagonal radial side, and a minimum diagonal axial side, the minimum diagonal axial side being 0.2 to 5 times the maximum diagonal radial side; wherein each of the first teeth is, in a front view, configured to present the apex, the isosceles slant sides, and two side slants, an angle being formed by the isosceles slant side and the two side slants, and having a range of 1°˜45°.

8. The substrate carrier for solar cells as claimed in claim 1, wherein each of the first teeth is, in a side view, configured to present a gradually varying ellipsoid which has a minimum ellipse of a first major axis at its top end and a maximum ellipse of a second major axis at its bottom end, and a major axis slant side being formed between the first and second major axes; wherein an angle, formed between the major axis slant side and a line passing through the center of the ellipsoid and the center of the rod, has a range of 1°˜45°.

9. The substrate carrier for solar cells as claimed in claim 8, wherein each of the first teeth is, in a front view, configured to present a minimum ellipse of a first minor axis, and a maximum ellipse of a second minor axis, a minor axis slant side being formed between the first and second minor axes; wherein an angle, formed between the minor axis slant side and a line passing through the center of the ellipsoid and the center of the rod, has a range of 1°˜45°, and the minor axis slant side is 0.5 to 5 times the minimum ellipse minor axis.

10. The substrate carrier for solar cells as claimed in claim 1, wherein the carrier made of PFA material is provided with following characteristics: a density of between 2 and 2.5, a melting point between 280° C. to 350° C., a tensile strength of between about 20 to 38 MPa, an elastic modulus of between 445 to 730 MPa at room temperature, and a limiting oxygen index (LOI) of at least 95%.

11. The substrate carrier for solar cells as claimed in claim 1, wherein the press rod is further extended outwardly from the droplet projection to form a protrusion, so as to allow a user to grasp it for guiding the press rod into the recess of the side plate.

12. The substrate carrier for solar cells as claimed in claim 11, wherein the droplet projection of the press rod is extended inwardly to form a round protrusion such that when the press rod is positioned and engaged in the recess of the side plate, the round protrusion is pressed tightly against the inner portion of the side plate.

13. The substrate carrier for solar cells as claimed in claim 12, wherein when the press rod is positioned to engage the recess of the side plate, the first teeth on the press rod are adapted to face toward and contact the upper portion of the solar cell substrate.

14. The substrate carrier for solar cells as claimed in claim 11, wherein the droplet projection is further provided with a major axis and a minor axis such that the major axis has a length of 1.1 to 1.5 times the length of the minor axis, the recess of the side plate is further provided with a U-shape notch corresponding to the major and minor axes, the U-shape notch is provided with a slant face at its both entry sides for guiding the press rod; wherein the U-shape notch on its both sides of a bottom end is provided respectively with a first diameter arc portion and a second diameter arc portion to restrict movement of the major and minor axes of the droplet projection, so as to ensure that the press rod is rotated in a predetermined directional rotation for a predetermined distance, and the press rod is further rotated and engaged in the recess of the side plate.

15. The substrate carrier for solar cells as claimed in claim 11, wherein the recess of the side plate is further provided with an L-shape notch, and a slant face is formed respectively on each of two entry sides of the L-shape notch to guide the press rod; wherein the L-shape notch on its down side is provided with an inner opening from which a side round arc is extended to be formed so as to match a top end of the droplet projection; wherein the side round arc has a diameter greater than the length of the inner opening to ensure that the press rod is shifted a predetermined distance along a predetermined shifting direction such that the press rod is fastened and fixed in the recess of the side plate.

16. The substrate carrier for solar cells as claimed in claim 15, wherein the L-shape notch further comprises a guiding slant face respectively on two sides of the lower portion thereof.

17. The substrate carrier for solar cells as claimed in claim 14, wherein the first diameter arc portion and the second diameter arc portion have different diameters, so as to ensure that the press rod is rotated in a predetermined direction.

18. The substrate carrier for solar cells as claimed in claim 1, wherein a hook slot is provided near each of both sides of the recess of the side plate, and the hook slot is hung by a robotic arm to hold the carrier; wherein a central portion of the side plate is provided with a plurality of positioning holes for the user to hold the carrier, or to position the carrier in a processing machine; wherein a guide slant face is disposed respectively in the hook slot, in a corner of the side plate close to the hook slot, and inside each of the positioning holes, the guide slant face having an angle, in a range of 10°˜80°.

19. The substrate carrier for solar cells as claimed in claim 18, wherein the side plate is further provided with a refraction section on its side, so as to facilitate the carrier to be positioned in a wet etching tank in the wet etching process.

20. The substrate carrier for solar cells as claimed in claim 19, wherein the retraction section is further disposed with a RFID tag to facilitate manufacturing follow-up of the carrier.
